(19) United States
(12) Patent Application Publication
(10) Pub. No.: US 2017/0137328 A1
(43) Pub. Date: May 18, 2017

(54) METHOD OF MAKING A CERAMIC WAVELENGTH CONVERTER ASSEMBLY

(71) Applicant: OSRAM SYLVANIA INC., Wilmington, MA (US)

(72) Inventors: John F. Kelso, Exeter, NH (US); Alan Lenef, Belmont, MA (US); Alan Piquette, Peabody, MA (US)

(73) Assignee: OSRAM SYLVANIA Inc., Wilmington, MA (US)

(21) Appl. No.: 15/320,110

(22) PCT Filed: Jun. 17, 2015
(86) PCT No.: PCT/US2015/036256

§ 371 Date: Dec. 19, 2016

Related U.S. Application Data
(60) Provisional application No. 62/013,806, filed on Jun. 18, 2014.

(51) Int. Cl. C04B 37/00; B32B 37/06; B32B 7/12; C09K 11/77; B32B 18/00

(52) U.S. Cl. CPC C04B 37/005; C09K 11/7774; B32B 18/00; B32B 7/12; B32B 37/06; C04B 2237/062; C04B 2237/343; C04B 2237/708; B32B 2307/40; B32B 2315/02; B32B 2551/00; H01L 33/502

(57) ABSTRACT

There is herein described a method for forming a ceramic wavelength converter assembly which achieves a direct bonding of an alumina-based ceramic wavelength converter to an alumina-based ceramic substrate such as polycrystalline or sapphire. The method comprises applying a silica-containing layer between the converter and the substrate and then applying heat to bond the converter to the substrate to form the ceramic wavelength converter assembly. Because direct bonding is achieved, the ceramic wavelength converter may operate at much higher incident light powers than conventional silicone glue-bonded converters.

### CROSS-REFERENCE TO RELATED APPLICATIONS

The present application is an international application of, and claims priority to, U.S. Provisional Application No. 62/013,806, filed Jun. 18, 2014, the entire contents of which are hereby incorporated by reference.

### BACKGROUND

Solid, sintered ceramic wavelength converters are known for use with light-emitting diodes (LEDs) to convert the shorter wavelength monochromatic light emitted by the LED into a longer wavelength secondary light emission. The ceramic wavelength converters are formed by sintering a mass of inorganic phosphor particles at high temperature until the particles diffuse and stick together to form a monolithic piece. Typically, the sintered piece has a density that approaches the theoretical density for the material. In some applications, it is desirable to maintain some porosity to enhance scattering. In others, it may be desirable to produce a substantially transparent material having little or no porosity.

The ceramic wavelength converters are combined with LEDs in applications where it is desired to produce a light emission having a different color than produced by the LED itself. For example, in applications where a white light emission is desired, it is known to partially convert a blue primary light emission from an LED into a yellow secondary light and combine the yellow secondary light emission with the remainder of the unconverted blue primary light to produce an overall white light emission. One of the most commonly used ceramic converters for white light applications is comprised of a cerium-activated yttrium aluminum garnet (YAG:Ce) phosphor.

Because of their higher thermal conductivity, ceramic wavelength converters are preferred in higher power applications over converters that are formed from dispersions of phosphor particles in epoxy or silicone resins. In particular, ceramic wavelength converters are preferred for high luminance display or projection applications utilizing focused or tightly-collimated laser excitation. The high incident flux of the laser excitation results in a large amount of heat being generated within a relatively small area within the converter. The heat generated by the down-conversion (Stokes shift) and other non-radiative losses within the phosphor must be effectively dissipated so that degradation or thermal quenching of the phosphor may be avoided.

Existing laser-activated remote phosphor (LARP) devices used in high luminance display or projection applications may employ mechanical means such as, for example, phosphor powder embedded in silicone on a rotating and reflective color wheel to avoid overheating by minimizing duty cycle. However, this approach requires additional mechanical components that must maintain very tight tolerances, and large amounts of phosphor. Alternative approaches employ luminescent ceramic plates attached to heat conductive substrates with heat-resistant silicone adhesives. This solution is also problematic in that the silicone adhesives that have the optical properties needed in LARP devices are poor heat conductors (typically <1 W/(m·K)), and thus, overheating remains a problem.

### SUMMARY

Sapphire and polycrystalline alumina (PCA) are useful alumina (Al₂O₃)-based substrates for ceramic wavelength converters. Both materials have high thermal conductivities (>about 20 W/(m·K)) and are highly transmissive to visible light. These properties make them desirable for transmissive LARP applications in which laser light is incident on one side of the converter and secondary light emission occurs from the opposite side of the converter. This means that either the laser light or the secondary emission must pass through the substrate as compared to a reflective LARP application wherein the secondary emission is directed back towards the incident laser light.

In order to take full advantage of the properties of these materials, it is necessary to bond the ceramic wavelength converter directly to the PCA or sapphire substrate without use of an adhesive. As described above, most silicone adhesives are poor heat conductors and would form a thermal barrier between the converter and the substrate. U.S. Patent Publication 2005/0269582 describes directly bonding a luminescent YAG:Ce ceramic to sapphire by diffusion bonding. However, the method described therein requires hot pressing of the two materials under high temperatures (1700° C.) and pressures (300 bar) which could lead to degradation or cracking of the luminescent ceramic or substrate.

The present method achieves a direct bonding of an alumina-based ceramic wavelength converter to an alumina-based ceramic substrate such as PCA or sapphire at a lower temperature and preferably with no applied pressure. In particular, a silica-containing layer is applied between an alumina-based ceramic wavelength converter and an alumina-based ceramic substrate. The ceramic wavelength converter and substrate are then bonded together by applying heat to form a ceramic wavelength converter assembly. Preferably, the ceramic wavelength converter and substrate are heated in a reducing atmosphere at a temperature of less than 1500° C. More preferably, they are heated in a wet hydrogen atmosphere to minimize damage to the luminescent ceramic.

As mentioned above, ceramic wavelength converters subjected to high power excitation (pump) sources such as blue lasers experience a significant amount of heating due to Stokes-shift losses and other non-radiative losses. Removing this heat from the ceramic wavelength converter is needed to prevent thermal roll-over, a loss of output power with increasing input power. By directly bonding the ceramic wavelength converter to a transparent/translucent, high thermal conductivity substrate, a high lumen output may be obtained while reducing the harmful effects of Stokes-loss heating. Thus, the present invention provides an effective means to remove heat from a ceramic wavelength converter and is particularly suited for use in a transmission mode LARP device.

### BRIEF DESCRIPTION OF THE DRAWINGS

FIG. 1 illustrates a transmission mode LARP application which employs a ceramic wavelength converter assembly in accordance with an embodiment of the invention.

FIG. 2 illustrates a method in accordance with an embodiment of the invention.

FIG. 3 is an SEM photomicrograph of a cross section of a wavelength converter assembly formed by a method of the invention.

FIG. 4 is a graphical comparison of the average relative luminance/incident light power of wavelength converter assemblies (direct-bonded and glued) as a function of incident laser light power.

### DETAILED DESCRIPTION

[For a better understanding of the present invention, together with other and further objects, advantages and capabilities thereof, reference is made to the following disclosure and appended claims taken in conjunction with the above-described drawings.

References to the color of a phosphor, LED or conversion material refer generally to its emission color unless otherwise specified. Thus, a blue LED emits a blue light, a yellow phosphor emits a yellow light and so on.

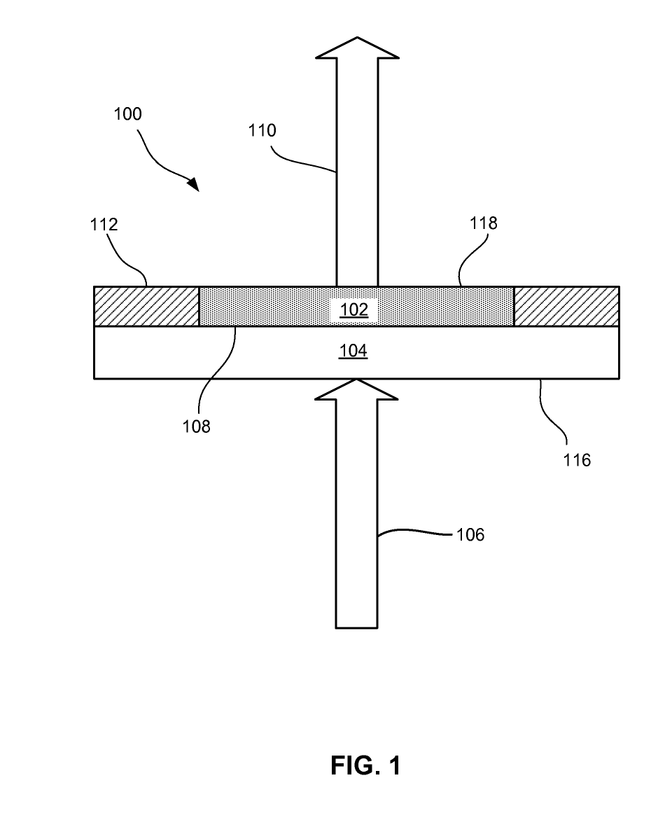

FIG. 1 illustrates a transmission mode LARP application which employs a ceramic wavelength converter assembly 100 in accordance with an embodiment of the present invention. The ceramic wavelength converter assembly 100 is comprised of a ceramic wavelength converter 102 which is bonded to substrate 104 at interface 108. Laser light 106 is directed onto the surface 116 of substrate 104 which is at least partially transmissive to the incident laser light 106. The laser light 106 passes through substrate 104 and excites ceramic wavelength converter 102 causing at least a partial conversion of laser light 106 into a secondary emission 110 which is emitted from surface 118 on the opposite side of the converter assembly 100. The converter assembly 100 is mated with a heat sink 112 which facilitates removal of the heat generated within the ceramic wavelength converter.

Preferably, the substrate 104 is substantially transmissive to the incident laser light 106 and transmits greater than 85%, greater than 90%, or even greater than 95% of the incident laser light. A translucent substrate may be used in some applications. However, the scattering of the incident laser light will cause expansion of the laser spot and therefore increase the emission spot size which is less desirable for LARP applications. Thus it is preferred that the substrate 104 should have an in-line transmission of greater than 80% and more preferably greater than 90% to minimize the expansion of the laser spot.

In a preferred embodiment, the ceramic wavelength converter 102 is comprised of an alumina (Al₂O₃)-based phosphor, for example, a luminescent yttrium aluminum garnet, Y₃Al₅O₁₂ (which may also be written as 3Y₂O₃.5Al₂O₃). Preferably, the ceramic wavelength converter is comprised of an alumina-based phosphor which may represented by the general formula A₃B₅O₁₂:Ce, wherein A is Y, Sc, La, Gd, Lu, or Tb and B is Al, Ga or Sc. Preferably, A is Y, Gd, Lu or Tb and B is Al. More preferably, the phosphor is one of Y₃Al₅O₁₂:Ce, (Y,Gd)₃Al₅O₁₂:Ce, Tb₃Al₅O₁₂:Ce, and Lu₃Al₅O₁₂:Ce, which may be referred to as YAG:Ce, YGdAG:Ce, TbAG:Ce and LuAG:Ce, respectively. The ceramic wavelength converter is preferably in the form of a flat rectangular plate or circular disc having a thickness of between 2 μm and 500 μm and preferably between 20 μm and 250 μm. The substrate 104 is preferably an alumina-based ceramic such as polycrystalline alumina (PCA) or sapphire. Other possible alumina-based ceramic substrates include spinel (Al₂O₃.MgO) and aluminum oxynitride (9Al₂O₃.5AlN).

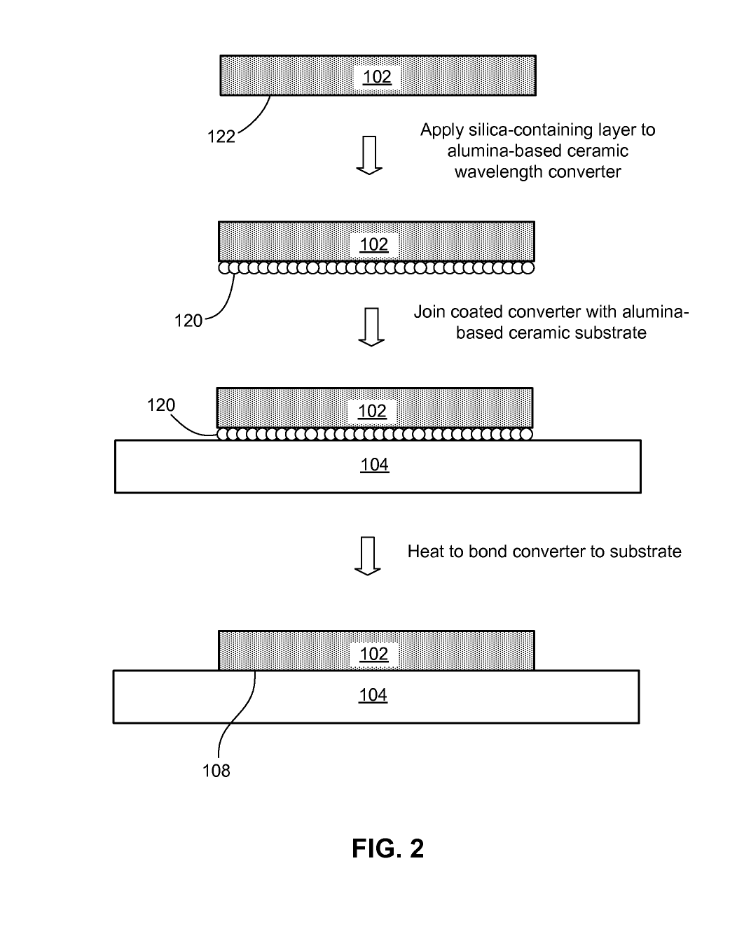

In order to bond the ceramic wavelength converter 102 to the substrate 104, a silica-containing layer (shown in FIG. 2) is applied to at least one of the surfaces that will form the interface 108 between the substrate 104 and ceramic wavelength converter 102. Preferably, the thickness of the silica-containing layer is 0.5 to 20 μm and more preferably 0.5 to 2 μm. The silica-containing layer may comprise a single layer or multiple layers of 0.5 to 1 μm silica spheres.

After the silica-containing layer is applied, the two parts are then joined together with the silica-containing layer in between them and heated to a temperature sufficient to create the bond. Preferably, this involves heating in an atmosphere that does not damage the phosphor, e.g., a reducing atmosphere such as wet hydrogen. The temperature should be sufficient to form a silica-containing liquid phase at the interface 108. Generally, this will occur by heating to a temperature of at least about 1300° C. Preferably, the temperature is raised to about 1450° C. for less than about one hour. This is considerably less than the 1700° C. temperature needed for diffusion bonding as taught by U.S. Patent Publication 2005/0269582.

An embodiment of the above process is illustrated in FIG. 2. In a first step, a layer of a silica-containing material 120 is applied to a surface 122 of ceramic wavelength converter 102. The silica-containing material is preferably comprised of silica microspheres, which may be applied by floating the silica microspheres of the surface of a liquid and then dipping the ceramic wavelength converter into the liquid one or more times to coat a sufficient layer of microspheres on the surface of the converter. In the next step, the coated ceramic wavelength converter 102 is joined with the alumina-based ceramic substrate 104 by placing the coated converter 102 onto the substrate 104 such that the layer of silica-containing material 120 is located between the ceramic wavelength converter 102 and substrate 104. In a final step, the entire assembly is heated at a temperature sufficient to bond the converter 102 to the substrate 104 along interface 108 while causing the substantial removal of the silica-containing layer 120.

By selecting the proper amount of silica, a bond is formed over substantially the entire interface 108 between the ceramic wavelength converter 102 and substrate 104. Preferably, the two parts are bonded over at least 90% of the interface and more preferably over at least 95% of the interface. Preferably, the silica-containing layer is removed by the bonding reaction resulting in a direct bond between the ceramic wavelength converter and the substrate without the presence of any intervening material that could negatively affect the heat transfer path from the converter into the substrate. It is believed that the silica-containing layer in its liquid phase at least partially reacts and/or is absorbed into one or more of the converter and/or substrate leaving no detectable secondary phases in the interface 108. As a result, there is formed a ceramic wavelength converter assembly suitable for use in a transmissive mode LARP application that has a reduced tendency for thermal roll-over at high lumen output.

### Examples

A thin layer of silica was applied by pulling polished discs of a ceramic wavelength converter comprised of a YGdAG:Ce phosphor through a layer of precipitated silica spheres (˜600 nm) floating on top of water. The spheres were deposited on the water by carefully dispensing the silica spheres, which were suspended in an n-butanol solution, in a drop-by-drop manner onto the water surface, forming a monolayer of the ˜600 nm silica spheres at the water-air interface. Portions of the surface of the water were left open for inserting the polished converter discs beneath the silica layer. The dipped coating was then dried in air at room temperature. This technique allows for silica coating to be applied only to the surface that is to be bonded to the substrate. Successive dips added more silica spheres to the surface of the converter as evidenced by a continuing change in optical appearance. Dipping the converter disc 5-7 times was determined to yield the amount of silica necessary to facilitate nearly 100% bonding.

The ceramic wavelength converters were then placed on polished sapphire or PCA substrates with the surface that was dip-coated with silica placed in contact with the substrate. Bonding was achieved by heating to 1450° C. for 30 minutes in wet hydrogen. This temperature was determined to be hot enough to facilitate a sufficient reaction between the converter and the substrate (>1300° C. to melt the silica in the presence of Al and Y and create the reaction). Other temperatures and atmospheres may work as long as they allow for the formation of a liquid phase or are not detrimental to the optical properties of the converter or substrate (e.g., an oxidizing atmosphere may covert cerium activator ions to a non-active oxidation state, damaging the phosphor). A liquid phase may not be necessary but is believed to facilitate bonding at lower temperatures and without applied pressure.

Good bonding was determined by observing the intimacy of contact while viewing the bonded ceramic wavelength converter assembly through the sapphire or PCA substrate under proper lighting conditions. Many samples exhibited bonding over 90% of the area between the converter and the substrate. The bond strength was also determined to be quite acceptable by not being able to break the bond when trying to shear the converter off the substrate by pushing on the side of the converter disc with tweezers parallel to the surface of the substrate.

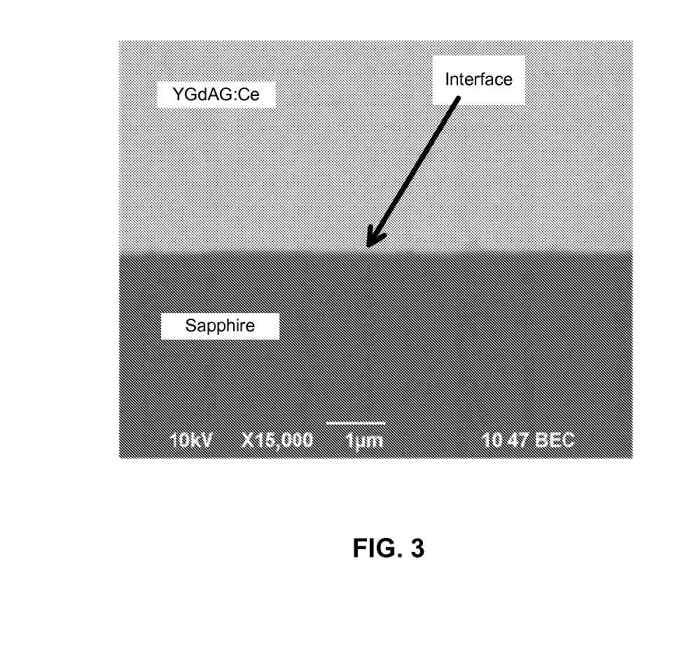

FIG. 3 is an SEM photomicrograph of a cross section of a bonded ceramic wavelength converter assembly according to this invention. In this case, a ceramic wavelength converter comprised of a YGdAG:Ce phosphor was bonded to a sapphire substrate after seven layers of 600 nm silica microspheres were applied. The cross sectional photomicrograph shows that there is an intimate contact between the YGdAG:Ce converter and sapphire substrate along the interface between the them. Moreover, the SEM photomicrograph reveals that the silica-containing layer was removed during the heating process leaving no apparent bonding layer or secondary phase at the interface.

The silica-containing layer is believed to have promoted a reaction between the sapphire and the ceramic wavelength converter as evidenced by a high bond strength. No silica or silicate glassy phase is observed under 2000 to 10,000 times magnification with an SEM. The silica, which forms a silicate liquid at the bonding temperature, was likely absorbed into the grain boundaries of the ceramic converter. As a result of the formation of a direct bond between the ceramic wavelength converter and the substrate, heat dissipation from the ceramic wavelength converter will not be impeded as it might be if a glass or silicone layer (lower thermal conductivities) had been used to make the bond.

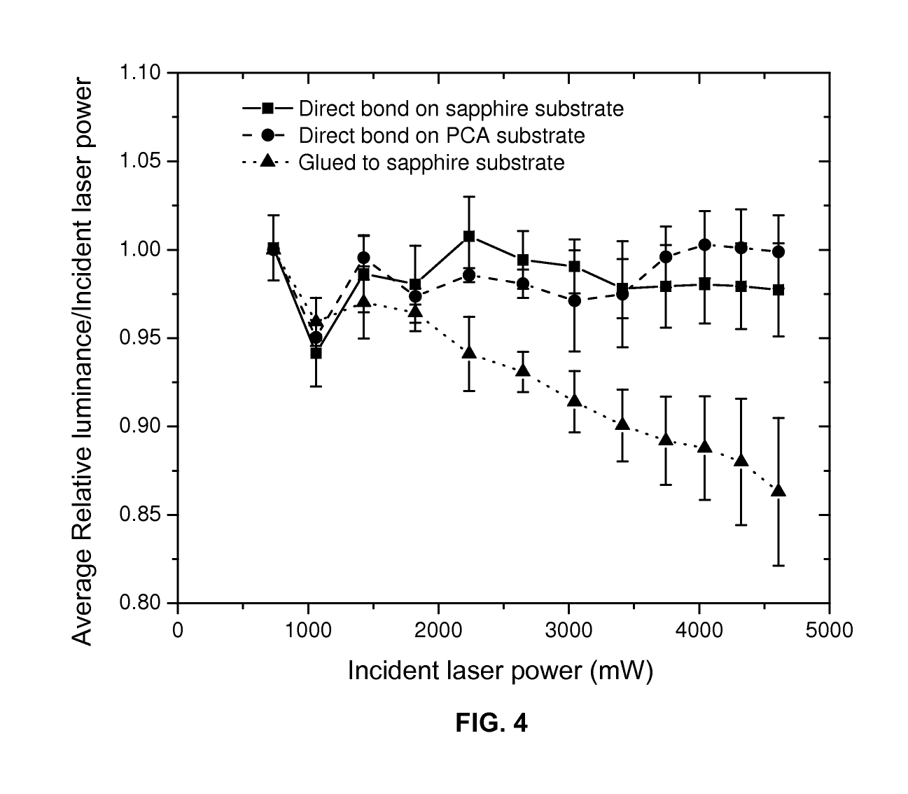

FIG. 4 is a comparison of the light conversion performance of direct-bonded wavelength converter assemblies made according to this invention with a silicone glue-bonded wavelength converter assembly. The wavelength converters in each case were excited with blue laser light in a transmission mode LARP setup (e.g., FIG. 1). The average relative luminance/incident light power for each group of samples was plotted as a function of incident laser light power. The data shows that above about 2000 mW the converter light output from the glued converter assembly starts to drop precipitously compared to the direct-bonded converter assemblies made according to this invention. This indicates that at higher powers the glued-converter assembly is unable to dissipate the heat generated by the Stokes loss in the converter leading a thermal runaway cycle in which heating of the converter further increases non-radiative absorption losses and thereby further increasing heat generation and increasing temperatures. This leads to very low conversion efficiencies or degradation of the wavelength converter and glue material. On the other hand, the converted light output of the direct-bonded converter assemblies is relatively constant over the entire range of incident light powers indicating adequate heat dissipation even at powers up to about 4500 mW.

While there have been shown and described what are at present considered to be preferred embodiments of the invention, it will be apparent to those skilled in the art that various changes and modifications can be made herein without departing from the scope of the invention as defined by the appended claims.

1. A method of making a wavelength converter assembly comprising:
(a) applying a silica-containing layer to a surface of at least one of a ceramic wavelength converter and a light-transmissive substrate, wherein the ceramic wavelength converter is comprised of an alumina-based phosphor and the substrate is comprised of an alumina-based ceramic;
(b) joining the ceramic wavelength converter to the substrate to form an assembly wherein the silica-containing layer is disposed at an interface between the ceramic wavelength converter and the substrate; and
(c) heating the assembly to bond the ceramic wavelength converter to the substrate.

2. The method of claim 1 wherein silica-containing layer comprises silica spheres.

3. The method of claim 2 wherein the silica spheres have a diameter from 0.5 to 1 μm.

4. The method of claim 2 wherein the silica-containing layer is applied by floating a layer of silica spheres on a liquid and dipping the ceramic wavelength converter or substrate into the liquid.

5. The method of claim 1 wherein the silica-containing layer has a thickness from 0.5 to 20 μm.

6. The method of claim 1 wherein the silica-containing layer has a thickness from 0.5 to 2 μm.

7. The method of claim 1 wherein the alumina-based phosphor has a general formula A3B5O12:Ce, wherein A is Y, Sc, La, Gd, Lu, or Tb and B is Al, Ga or Sc.

8. The method of claim 7 wherein A is Y, Gd, Lu or Tb and B is Al.

9. The method of claim 1 wherein the alumina-based phosphor comprises one of Y3Al5O12:Ce, (Y,Gd)3Al5O12:Ce, Tb3Al5O12:Ce, and Lu3Al5O12:Ce.

10. The method of claim 1 wherein the substrate comprises one of polycrystalline alumina and sapphire.

11. The method of claim 7 wherein the substrate comprises one of polycrystalline alumina and sapphire.

12. The method of claim 11 wherein the silica-containing layer has a thickness from 0.5 to 20 μm.

13. The method of claim 1 wherein the assembly is heated at a temperature sufficient to form a silica-containing liquid phase at the interface.

14. The method of claim 13 wherein the temperature less than 1500° C.

15. The method of claim 1 wherein the ceramic wavelength converter and the substrate are bonded over at least 90% of the interface.

16. A method of making a wavelength converter assembly comprising:
(a) applying a layer of silica spheres to a surface of at least one of a ceramic wavelength converter and a light-transmissive substrate, wherein the ceramic wavelength converter is comprised of an alumina-based phosphor selected from Y3Al5O12:Ce, (Y,Gd)3Al5O12:Ce, Tb3Al5O12:Ce, and Lu3Al5O12:Ce and the substrate is comprised of one of polycrystalline alumina and sapphire;
(b) joining the ceramic wavelength converter to the substrate to form an assembly wherein the silica-containing layer is disposed at an interface between the ceramic wavelength converter and the substrate; and
(c) heating the assembly in a reducing atmosphere at a temperature of less than 1500° C. to bond the ceramic wavelength converter to the substrate.

17. The method of claim 16 wherein the assembly is heated in a wet hydrogen atmosphere.

18. The method of claim 16 wherein a silica-containing liquid phase is formed in the interface during heating.

19. The method of claim 16 wherein the silica spheres are applied by floating a layer of the silica spheres on a liquid and dipping the ceramic wavelength converter or substrate into the liquid.

20. The method of claim 16 wherein the layer of silica spheres has a thickness from 0.5 to 20 μm.
